(19) United States
(12) Patent Application Publication
(10) Pub. No.: US 2012/0049075 A1
(43) Pub. Date: Mar. 1, 2012

(54) Radiation detector, radiographic imaging device, and method of fabricating radiation detector

(75) Inventor: Fumito Nariyuki, Kanagawa (JP)

(73) Assignee: FUJIFILM Corporation, Tokyo (JP)

(21) Appl. No.: 13/137,117

(22) Filed: Jul. 21, 2011

(30) Foreign Application Priority Data
Aug. 31, 2010 (JP) 2010-193874

(51) Int. Cl. G01T 1/20; G01T 1/202; H01L 31/18

(52) U.S. Cl. 250/368; 438/69; 257/E31.129

(57) ABSTRACT

There is provided a radiation detector including: a light detecting substrate that converts light into charges; a scintillator layer that faces the light detecting substrate and converts irradiated radiation into light; and a reflecting portion that reflects light, converted at the scintillator layer, toward the light detecting substrate, and is disposed so as to face the scintillator layer and so as to be able to be displaced relative to the scintillator layer in an in-plane direction.

### CROSS-REFERENCE TO RELATED APPLICATION

This application is based on and claims priority under 35 USC 119 from Japanese Patent Application No. 2010-193874 filed on Aug. 31, 2010, the disclosure of which is incorporated by reference herein.

### BACKGROUND

1. Technical Field

The present invention relates to a radiation detector, a radiographic imaging device, and a method of fabricating a radiation detector.

2. Related Art

FPDs (Flat Panel Detectors), in which a radiation-sensitive layer is disposed on a TFT (Thin Film Transistor) active matrix substrate and that detect irradiated radiation such as

X-rays or the like and directly convert the radiation into data of a radiographic image, that expresses the distribution of the irradiated radiation amount, and output the data, have been put into practice in recent years. Portable radiographic imaging devices (hereinafter also called electronic cassettes), that incorporate therein a panel-type radiation detector such as an FPD or the like, and electronic circuits including an image memory, and a power source section, and that store the radiographic image data outputted from the radiation detector in the image memory, have also been put into practice. Because the electronic cassette has excellent portability, images of a subject can be captured while the subject lies as is on a stretcher or a bed, and it is also easy to adjust the region to be imaged by changing the position of the electronic cassette. Therefore, even cases in which images of a subject who cannot move are to be captured can be dealt with flexibly.

Various structures have been proposed for the above-described radiographic image detector. For example, there is known an indirect-conversion-type radiographic image detector that once converts irradiated radiation into light at a scintillator layer, and again converts the light, that is discharged from the scintillator layer, into charges by a light detecting substrate, and accumulates the charges.

As a mode of an indirect-conversion-type radiographic image detector, for example, there is a method in which a structure, in which a scintillator formed from CsI:Tl or the like is deposited on a supporting substrate (a reflective substrate), is affixed to a light detecting substrate by using an adhesive or a self-adhesive. In addition, there are also a direct depositing method in which a scintillator formed from CsI:Tl or the like is directly deposited on a light detecting substrate and a reflecting layer is deposited thereon as needed, and a method in which a scintillator formed from GOS (Gd₂O₂S:Tb) or the like is coated on a light detecting substrate, and a method in which a structure, in which a scintillator layer formed from GOS is coated on a supporting substrate, is affixed on a light detecting substrate.

However, a metal plate (generally an Al substrate) is used as the supporting substrate of the scintillator in the above-described affixing method. Therefore, after the light detecting substrate is affixed to the scintillator layer, if the radiation detector is used with the metal plate remaining as is, warping may arise due to the difference in the thermal expansion coefficients of the light detecting substrate and the metal plate.

Further, with the above-described direct conversion method and coating method as well, similarly, when the reflecting layer is grown on the scintillator layer, warping may arise due to the difference in the thermal expansion coefficients of the light detecting substrate and the reflecting layer.

As a countermeasures to this warping, Japanese Patent No. 4451843 and Japanese Patent Application Laid-Open (JP-A) No. 2005-172511 disclose methods of peeling a supporting substrate off from a scintillator layer that has the supporting substrate and a reflecting layer.

However, in Japanese Patent No. 4451843 and JP-A No. 2005-172511, because the light detecting substrate is affixed to the scintillator layer, the reflecting layer and the scintillator layer and the light detecting substrate are integral and thermally expand, and warping may arise due to the difference in the thermal expansion coefficients of the light detecting substrate and the reflecting layer.

### SUMMARY

The present invention was made in view of the above-described circumstances, and an object thereof is to provide a radiation detector, a radiographic imaging device, and a method of fabricating a radiation detector that suppress warping of a light detecting substrate.

A first aspect of the present invention provides a radiation detector including:

a light detecting substrate that converts light into charges;

a scintillator layer that faces the light detecting substrate and converts irradiated radiation into light; and

a reflecting portion that reflects light, converted at the scintillator layer, toward the light detecting substrate, and is disposed so as to face the scintillator layer and so as to be able to be displaced relative to the scintillator layer in an in-plane direction.

Here, the “in-plane direction” means an in-plane direction of the light detecting substrate.

In this structure, even if the thermal expansion amounts (displacement amounts) in the in-plane direction of the light detecting substrate and the reflecting portion are different, since the reflecting portion and the scintillator layer are disposed so as to face one another and so as to be able to be displaced relatively in the in-plane direction, i.e., can be displaced without being restrained by one another, warping of the light detecting substrate, that is due to the difference in the thermal expansion amounts of the reflecting portion and the light detecting substrate, can be suppressed.

A second aspect of the present invention provides the radiation detector of the first aspect, wherein the reflecting portion planarly contacts the scintillator layer.

In accordance with this structure, the reflecting portion or the scintillator layer can be supported at the contact surface.

A third aspect of the present invention provides the radiation detector of the second aspect, wherein a contact surface of the reflecting portion or the scintillator layer is subjected to a sliding treatment.

In accordance with this structure, by carrying out sliding treatment and reducing the friction of the contact surface of the reflecting portion or the scintillator layer, the reflecting portion and the scintillator layer being restrained by one another due to the friction and displacing can be suppressed.

A fourth aspect of the present invention provides the radiation detector of the first aspect, wherein the reflecting portion is supported such that an air layer is formed between the reflecting portion and the scintillator layer.

In accordance with this structure, the reflectance of light at the reflecting portion can be increased due to the effects of the refractive index of the air layer.

A fifth aspect of the present invention provides the radiation detector of the fourth aspect, wherein a spacer, that makes a distance between the reflecting portion and the scintillator layer constant, is provided between the reflecting portion and the scintillator layer.

In accordance with this structure, the reflecting portion or the scintillator layer can be supported by the spacer. Further, the air layer can be formed between, for example, plural fine particles that structure the spacer.

A sixth aspect of the present invention provides the radiation detector of the first aspect, wherein the scintillator layer is structured so as to include a plurality of columnar crystals.

As the scintillator layer, for example, a scintillator including columnar crystals such as CsI, for example, may be used. Further, the scintillator layer may include a non-columnar crystal region formed from plural non-columnar crystals and is continuous with the columnar crystal region.

A seventh aspect of the present invention provides the radiation detector of the sixth aspect, wherein distal ends of the columnar crystals face the light detecting substrate.

Here, the distal ends of the columnar crystals mean ends that are farer from a supporting substrate at the time of forming the columnar crystals on the supporting substrate.

An eighth aspect of the present invention provides the radiation detector of the first aspect, further including a sealing portion that encloses and seals the entire scintillator layer.

In accordance with this structure, water and the like can be prevented from contacting the scintillator layer, which is particularly effective in cases in which the scintillator layer is deliquescent.

A ninth aspect of the present invention provides the radiation detector of the first aspect, further including a frame portion that connects the light detecting substrate and the reflecting portion.

Here, the frame portion may be a flexible member.

In accordance with this structure, water and the like can be reliably prevented from contacting the scintillator layer. Further, when a flexible frame member is used, the light detecting substrate and the reflecting plate can be displaced without being restrained by one another. Therefore, warping of the light detecting substrate, that is due to a difference in the thermal expansion amounts of the light detecting substrate and the reflecting plate, can be suppressed.

A tenth aspect of the present invention provides a radiographic imaging device including:

a housing; and

the radiation detector of claim 1, incorporated within the housing,

wherein the light detecting substrate of the radiation detector is an irradiation surface of the radiation.

In accordance with this structure, radiation hits the scintillator layer and the reflecting portion in order from the light detecting substrate that is the irradiation surface of the radiation.

At this time, within the scintillator layer, the radiation is first irradiated onto the scintillator portion at the light detecting substrate side. Therefore, this scintillator portion at the light detecting substrate side mainly absorbs the radiation and emits light. Further, when the scintillator portion that mainly absorbs the radiation and emits light within the scintillator layer is the light detecting substrate side, the distance between that scintillator portion and the light detecting substrate is close, and the amount of light that the light detecting substrate receives from the scintillator layer can be increased.

In particular, in the structure of the seventh aspect, when the light detecting substrate is the irradiation surface of the radiation, the scintillator portion that mainly absorbs the radiation and emits light within the scintillator layer is the columnar crystal region at the light detecting substrate side. Therefore, there is even less light scattering, and the amount of light that is received at the light detecting substrate can be increased further.

An eleventh aspect of the present invention provides a radiographic imaging device including:

a housing; and

the radiation detector of claim 1, incorporated within the housing,

wherein the reflecting portion of the radiation detector is supported at the housing.

In accordance with this structure, it is possible to form only the air layer of the fourth aspect between the reflecting portion and the scintillator layer. Accordingly, a spacer such as that of the fifth aspect is not needed.

An twelfth aspect of the present invention provides a radiographic imaging device including a housing and a radiation detector incorporated within the housing, wherein the radiation detector comprises, in order from an irradiating direction of radiation:

a light detecting substrate that converts light into charges;

a scintillator layer that is disposed such that the light detecting substrate and distal ends of columnar crystals face one another, and that converts the irradiated radiation into light; and

a reflecting portion that is layered as a thin film on surfaces of ends, opposite the distal ends, of the columnar crystals, and that reflects, toward the light detecting substrate, light converted at the scintillator layer.

In general, the amount of displacement (amount of thermal expansion) of a reflecting portion is proportional to the thickness thereof. In accordance with structure of the twelfth aspect, the reflecting portion is made to be a thin film, and therefore, the amount of displacement of the reflecting portion can be reduced, and accordingly, warping of the light detecting substrate can be suppressed.

Further, in accordance with this structure, the radiation hits the scintillator layer and the reflecting portion in that order from the light detecting substrate.

At this time, the radiation is first irradiated at the scintillator portion at the light detecting substrate side within the scintillator layer. Therefore, this scintillator portion at the light detecting substrate side mainly absorbs the radiation and emits light. Further, when the scintillator portion that mainly absorbs the radiation and emits light within the scintillator layer is the light detecting substrate side, the distance between that scintillator portion and the light detecting substrate is close, and the amount of light that is received at the light detecting substrate can be increased.

A thirteenth aspect of the present invention provides a method of fabricating the radiation detector of the eighth aspect, including:

forming, on a supporting substrate, a first sealing film that structures the sealing portion;

forming the scintillator layer on the first sealing film;

forming a second sealing film, that structures the sealing portion, so as to cover the scintillator layer and the first sealing film;

affixing the light detecting substrate on the second sealing film; and

removing the supporting substrate from the first sealing film,

wherein, before forming the first sealing film, or after forming the first sealing film and before forming the scintillator layer, a surface treatment is carried out on the supporting substrate or the first sealing film such that an adhesive strength between the supporting substrate and the first sealing film is lower than an adhesive strength between the first sealing film and the scintillator layer.

In accordance with this method, in the removing of the supporting substrate from the first sealing film, the supporting substrate can be removed easily without the first sealing film being peeled-off from the scintillator layer.

A fourteenth aspect of the present invention provides a method of fabricating the radiation detector of the eighth aspect, including:

forming, on a supporting substrate, a first sealing film that structures the sealing portion;

forming the scintillator layer on the first sealing film;

forming a second sealing film, that structures the sealing portion, so as to cover the scintillator layer and the first sealing film;

affixing the light detecting substrate on the second sealing film;

cutting, after forming the second sealing film and before affixing the light detecting substrate, or after affixing the light detecting substrate, in an out-of-plane direction of the supporting substrate, the first sealing film and the second sealing film, which are at an outer peripheral side of the scintillator layer; and

removing the supporting substrate from the first sealing film,

wherein, before forming the first sealing film, a surface treatment is carried out on the supporting substrate such that an adhesive strength between the supporting substrate and a portion of the first sealing film, that is at an outer peripheral side of a formation region of the scintillator layer, is higher than an adhesive strength between the supporting substrate and a portion of the first sealing film that is beneath the formation region of the scintillator layer.

In accordance with this method, at the time of the forming of the scintillator layer, the adhesive strength between the supporting substrate and the first sealing film that is at an outer peripheral side of a formation region of the scintillator layer, is higher than an adhesive strength between the supporting substrate and the first sealing film that is beneath the formation region of the scintillator layer. Therefore, for example, the first sealing film and the scintillator layer can be prevented from being peeled-off from the supporting substrate. Further, at the time of the removing of the supporting substrate from the first sealing film, it suffices to remove the supporting substrate from only the first sealing film that is beneath the formation region of the scintillator layer because the first sealing film and the second sealing film, that are at the outer peripheral side of the scintillator layer and whose adhesive strength is high, are cut in the out-of-plane direction of the supporting substrate. Here, the adhesive strength between the supporting substrate and the first sealing film, that is beneath the formation region of the scintillator layer, is lower than the adhesive strength between the supporting substrate and the first sealing film, that is at the outer peripheral side of the formation region of the scintillator layer. Therefore, the supporting substrate can be removed easily.

In accordance with the present invention, there can be provided a radiation detector, a radiographic imaging device, and a method of fabricating a radiation detector that suppress warping of a light detecting substrate.

### BRIEF DESCRIPTION OF THE DRAWINGS

Exemplary embodiments of the present invention will be described in detail based on the following figures, wherein:

FIG. 1 is a schematic drawing showing the placement of an electronic cassette at a time of radiographic image capturing;

FIG. 2 is a schematic perspective view showing the internal structure of the electronic cassette;

FIG. 3 is a drawing showing a circuit diagram of the electronic cassette;

FIG. 4 is a sectional view showing the sectional structure of the electronic cassette;

FIG. 5 is a sectional view showing the sectional structure of a radiation detector relating to a first exemplary embodiment of the present invention;

FIG. 6 is a sectional view showing the sectional structure of a radiation detector relating to a second exemplary embodiment of the present invention;

FIG. 7 is a sectional view showing the sectional structure of a radiation detector relating to a third exemplary embodiment of the present invention;

FIG. 8 is a sectional view showing the sectional structure of a radiation detector relating to a fourth exemplary embodiment of the present invention;

FIG. 9A through FIG. 9D are process diagrams of a method of fabricating a radiation detector relating to a fifth exemplary embodiment of the present invention; and

FIG. 10 is an explanatory drawing of a method of fabricating a radiation detector relating to a sixth exemplary embodiment of the present invention.

### DETAILED DESCRIPTION

### First Exemplary Embodiment

Hereinafter, a radiation detector, a radiographic imaging device, and a method of fabricating a radiation detector relating to a first exemplary embodiment are described concretely with reference to the appended drawings. Note that, in the drawings, members (structural elements) having the same or corresponding functions are denoted by the same reference numerals, and description thereof is omitted appropriately.

—Overall Structure of Radiographic Imaging Device—

First, the structure of an electronic cassette, which serves as an example of a radiographic imaging device that incorporates therein a radiation detector relating to the first exemplary embodiment of the present invention, is described.

An electronic cassette is a radiographic imaging device that is portable, and detects radiation that is from a radiation source and has passed through a subject, and generates image information of a radiographic image expressed by the detected radiation, and can store the generated image information. Concretely, the electronic cassette is structured as follows. Note that the electronic cassette may be a structure that does not store generated image information.

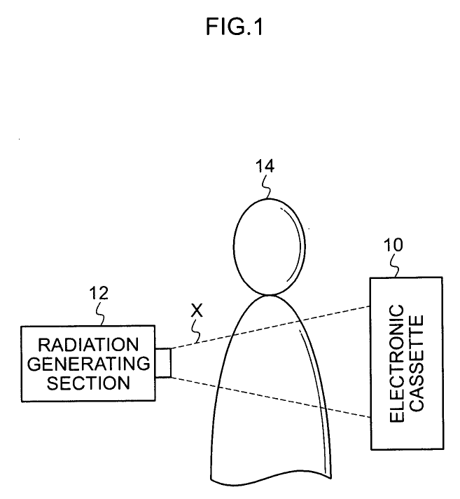

FIG. 1 is a schematic drawing showing the placement of an electronic cassette at the time of radiographic image capturing.

At the time of capturing a radiographic image, an electronic cassette 10 is placed with an interval between the electronic cassette 10 and a radiation generating section 12 that serves as a radiation source that generates radiation X. The region between the radiation generating section 12 and the electronic cassette 10 at this time is an imaging position for the positioning of a patient 14 serving as a subject. When capturing of a radiographic image is instructed, the radiation generating section 12 irradiates the radiation X of a radiation amount that corresponds to imaging conditions and the like that were given in advance. Due to the radiation X that is irradiated from the radiation generating section 12 passing through the patient 14 who is positioned at the imaging position, the radiation X carries image information, and thereafter, is irradiated onto the electronic cassette 10.

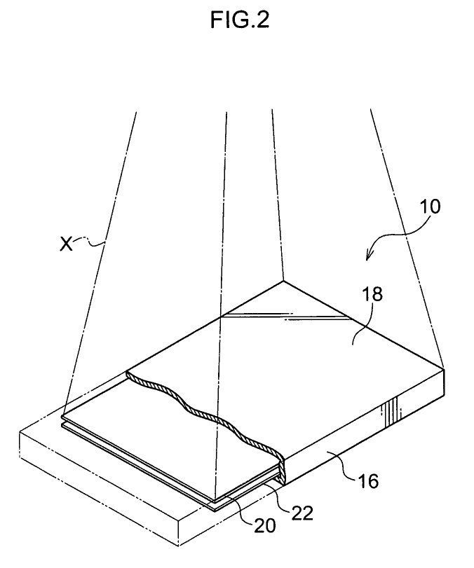

FIG. 2 is a schematic perspective view showing the internal structure of the electronic cassette 10.

The electronic cassette 10 is formed from a material through which the radiation X is transmitted, and has a housing 16 that is shaped as a flat plate and has a predetermined thickness. A radiation detector 20 that detects the radiation X that has passed through the patient 14, and a control substrate 22 that controls the radiation detector 20, are provided at the interior of the housing 16 in that order from an irradiation surface 18 side of the housing 16 onto which the radiation X is irradiated.

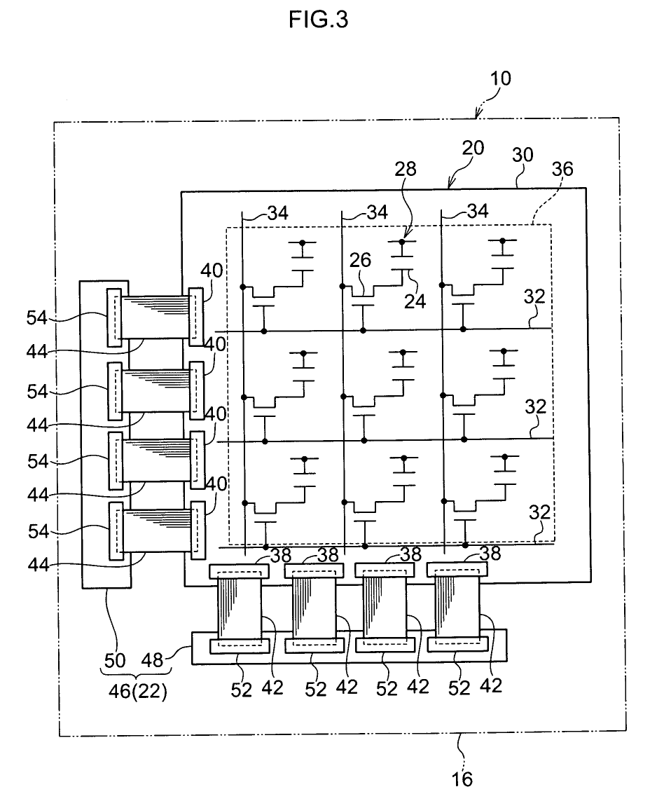

FIG. 3 is a drawing showing a circuit diagram of the electronic cassette 10.

The radiation detector 20 has a light detecting substrate 30 at which numerous pixels 28 are provided in two dimensions. Each of the pixels 28 is structured to include a sensor portion 24 that has an upper electrode, a semiconductor layer, and a lower electrode and that receives light and accumulates charges, and a TFT (Thin Film Transistor) switch 26 for reading-out the charges accumulated in the sensor portion 24.

Plural scan lines 32 for turning the TFT switches 26 on and off, and plural signal lines 34 for reading-out the charges accumulated in the sensor portions 24, are provided at the light detecting substrate 30 so as to intersect one another.

At the radiation detector 20 relating to the first exemplary embodiment of the present invention, a scintillator layer 36 is affixed to the obverse of the light detecting substrate 30.

The scintillator layer 36 converts the irradiated radiation X such as X-rays or the like into light. The sensor portions 24 receive the light illuminated from the scintillator layer 36 and accumulate charges.

Due to any of the TFT switches 26 that are connected to the signal line 34 being turned on, electric signals (image signals) expressing a radiographic image flow to the signal line 34 in accordance with the charge amounts accumulated in the sensor portions 24.

Further, plural connectors 38 for connection are provided so as to be lined-up at one end side, in the signal line 34 direction, of the radiation detector 20. Plural connectors 40 are provided so as to be lined-up at one end side in the scan line 32 direction. The respective signal lines 34 are connected to the connectors 38, and the respective scan lines 32 are connected to the connectors 40.

One end of a flexible cable 42 is electrically connected to the connector 38. Further, one end of a flexible cable 44 is electrically connected to the connector 40.

These flexible cables 42 and flexible cables 44 are joined to the control substrate 22.

A control section 46, that carries out control of the imaging operations by the radiation detector 20 and control of signal processings with respect to the electric signals that flow to the respective signal lines 34, is provided at the control substrate 22. The control section 46 has a signal detecting circuit 48 and a scan signal control circuit 50.

Plural connectors 52 are provided at the signal detecting circuit 48. The other ends of the flexible cables 42 are electrically connected to these connectors 52. The signal detecting circuit 48 incorporates therein, for each of the signal lines 34, an amplification circuit that amplifies the inputted electric signal. Due to this structure, the signal detecting circuit 48 amplifies, by the amplification circuits, the electric signals inputted from the respective signal lines 34 and detects the signals, and thereby detects the charge amounts accumulated in the respective sensor portions 24 as information of the respective pixels 28 that structure the image.

On the other hand, plural connectors 54 are provided at the scan signal control circuit 50. The other ends of the flexible cables 44 are electrically connected to these connectors 54. The scan signal control circuit 50 can output, to the respective scan lines 32, control signals for turning the TFT switches 26 on and off.

When capturing of a radiographic image is carried out in such a structure, the radiation X that has been transmitted through the patient 14 is irradiated onto the radiation detector 20. The irradiated radiation X is converted into light at the scintillator layer 36, and the light is illuminated onto the sensor portions 24. The sensor portions 24 receive the light illuminated from the scintillator layer 36 and accumulate charges.

At the time of image read-out, on signals (+10 to 20 V) are successively applied from the scan signal control circuit 50 via the scan lines 32 to the gate electrodes of the TFT switches 26 of the radiation detector 20. Due thereto, the TFT switches 26 of the radiation detector 20 are successively turned on, and electric signals corresponding to the charge amounts accumulated in the sensor portions 24 thereby flow-out to the signal lines 34. On the basis of the electric signals that have flowed-out to the signal lines 34 of the radiation detector 20, the signal detecting circuit 48 detects, as information of the respective pixels 28 structuring the image, the charge amounts accumulated in the respective sensor portions 24. Due thereto, image information, that expresses the image expressed by radiation irradiated onto the radiation detector 20, is obtained.

—Structure of Electronic Cassette 10—

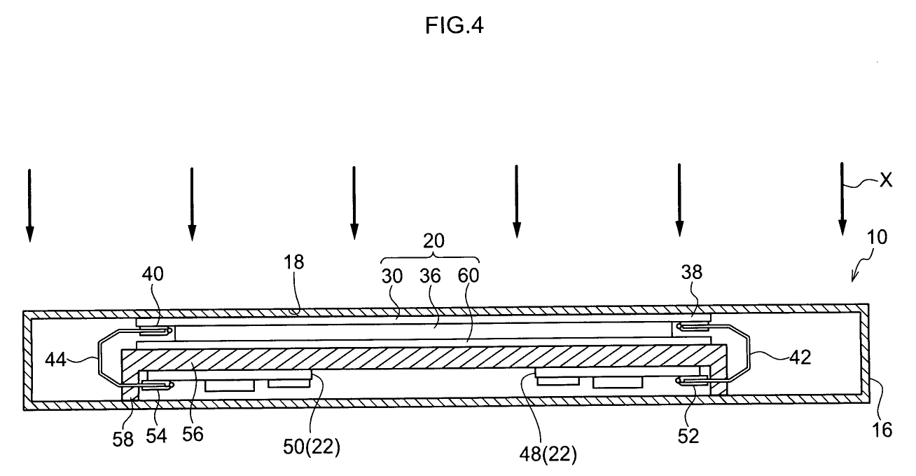

The structure of the electronic cassette 10 is described more concretely next. FIG. 4 is a sectional view showing the sectional structure of the electronic cassette 10.

As shown in FIG. 4, the control substrate 22, a base 56, and the radiation detector 20 relating to the first exemplary embodiment of the present invention are incorporated in the electronic cassette 10 at the interior of the housing 16 thereof, in that order from the side opposite the irradiation surface 18 on which the radiation X is irradiated.

The base 56 is placed, via supporting legs 58, on the bottom surface of the interior of the housing 16. The control substrate 22 is fixed to the bottom surface of the base 56. The radiation detector 20 is connected to the control substrate 22 via the above-described flexible cables 42 and flexible cables 44.

Note that, hereinafter, in the embodiments, “up” indicates the direction from the control substrate 22 side toward the radiation detector 20 side and “down” indicates the direction from the radiation detector 20 side toward the control substrate 22 side, for convenience of explanation. However, these are defined for convenience for understanding of the positional relationships and do not limit the respective directions described hereinafter.

The radiation detector 20 relating to the first exemplary embodiment of the present invention is rectangular flat plate shaped, and, as described above, detects the radiographic image that is manifested by the radiation X that has passed through the patient 14. The radiation detector 20 is fixed to the top surface (the ceiling plate) of the housing 16, and mainly has the light detecting substrate 30 that is connected to the other ends of the flexible cables 42 and the flexible cables 44, and the scintillator layer 36 that is affixed to the light detecting substrate 30, and a reflecting plate 60 (serving as a reflecting portion) that is placed on the top surface of the base 56.

The respective structures of the radiation detector 20 are concretely described hereinafter.

—Structure of Radiation Detector 20—

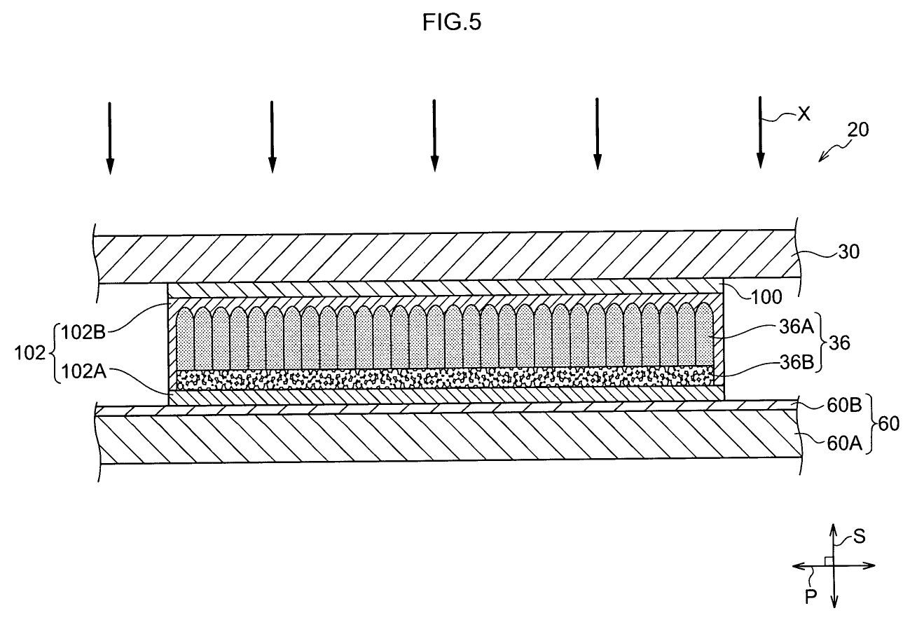

FIG. 5 is a sectional view showing the sectional structure of the radiation detector 20 relating to the first exemplary embodiment of the present invention.

The light detecting substrate 30 of the radiation detector 20 is structured by forming the TFT switches 26 and the sensor portions 24 on an unillustrated substrate. Further, the light detecting substrate 30 is the irradiation surface of the radiation X at the radiation detector 20. The radiation X is reverse-surface irradiated from the reverse surface side of the radiation detector 20 to which the scintillator layer 36 is not affixed.

Examples of substrate materials of the light detecting substrate 30 include inorganic materials such as YSZ (yttria-stabilized zirconia), glass and the like, and in addition thereto, organic materials such as saturated polyester resins, polyethylene terephthalate (PET) resins, polyethylene naphthalate (PEN) resins, polybutylene terephthalate resins, polystyrene, polycycloolefin, norbornene resins, poly(cyclotrifluoroethylene), cross-linked fumaric acid diester resins, polycarbonate (PC) resins, polyethersulfone (PES) resins, polysulfone (PSF, PSU) resins, polyarylate (PAR) resins, allyl diglycol carbonate, cyclic polyolefin (COP, COC) resins, cellulose resins, polyimide (PI) resins, polyamide-imide (PAI) resins, maleimide-olefin resins, polyamide (Pa) resins, acrylic resins, fluorine resins, epoxy resins, silicon resin films, polybenzazole resins, episulfide composites, liquid crystal polymers (LCP), cyanate resins, aromatic ether resins and the like, and the like. In addition, composite plastic materials of silicon oxide particles, composite plastic materials of metal nanoparticles, inorganic oxide nanoparticles, inorganic nitride nanoparticles or the like, composite plastic materials of metal or inorganic nanofibers and/or microfibers, composite plastic materials of carbon fibers or carbon nanotubes, composite plastic materials of glass flakes, glass fibers or glass beads, composite plastic materials of clay minerals or particles having a mica crystal structure, composite materials exhibiting a barrier performance and having at least one or more bonding interfaces due to a laminated plastic material having at least one bonding interface or an inorganic layer (e.g., SiO₂, Al₂O₃, SiOₓN_{y}) and an organic layer formed from the aforementioned materials being alternately laminated between a thin glass and an aforementioned single organic material, stainless or a metal laminated material in which stainless and a different type of metal are laminated, and an aluminum substrate or an aluminum substrate with an oxide covering film at which the insulating ability of the surface thereof is improved by carrying out an oxidizing treatment (e.g., an anodically oxidizing treatment) on the surface thereof, also can be used. When any of the aforementioned organic materials is used, it is preferable to use an organic material having excellent dimensional stability, solvent-resistance, electrical insulating ability, machinability, low air permeability, low moisture absorption ability, and the like.

Bio-nanofibers also can be used as the substrate material of the light detecting substrate 30. Bio-nanofibers are fibers in which a cellulose microfibril bundle (bacteria cellulose) that produces bacteria (acetic acid bacterium, Acetobacter Xylinum), and a transparent resin are compounded. The cellulose microfibril bundle has a width of 50 nm which is a size of 1/10 with respect to the visible light wavelength, and has high strength, high elasticity, and low thermal expansion. By impregnating and hardening a transparent resin, such as an acrylic resin, an epoxy resin or the like, in bacteria cellulose, bio-nanofibers that contain up to 60 to 70% fiber while still exhibiting light transmittance of about 90% at a wavelength of 500 nm, are obtained. Bio-nanofibers have a low thermal expansion coefficient (3-7 ppm) that is comparable to that of silicon crystal, have strength (460 MPa) to the same extent as that of steel, have high elasticity (30 GPa), and are flexible. Therefore, the light detecting substrate 30 can be formed to be thin as compared with a glass substrate or the like.

Further, a colorless, transparent aramid film also can be used. Aramid films are heat-resistant to 315° C., and have a thermal expansion coefficient that is near to that of glass substrates. Therefore, aramid films have the advantageous features that there is little warping after manufacture and breakage is difficult.

A self-adhesive layer 100 for affixing to the scintillator layer 36 is provided at the bottom surface of the light detecting substrate 30.

An acrylic, rubber, or silicon self-adhesive can be used as the self-adhesive that is used in the self-adhesive layer 100. However, from the standpoints of transparence and durability, acrylic self-adhesives are preferable. As the acrylic self-adhesive, it is preferable to use a self-adhesive whose main component is 2-ethylhexylacrylate or n-butylacrylate or the like and in which, in order to improve the cohesive force, a short-chain alkyl acrylate or methacrylate, such as, for example, methyl acrylate, ethyl acrylate or methyl methacrylate, and acrylic acid, methacrylic acid, an acrylamide derivative, maleic acid, hydroxylethyl acrylate, glycidyl acrylate or the like, that can become the cross-linking point with a cross-linking agent, are co-polymerized. The glass transition temperature (Tg) and cross-linking density can be varied by appropriately adjusting the mixing ratio and the types of the main component, the short-chain component and the component for adding the cross-linking point.

A sealing portion 102 that encloses and seals the entire scintillator layer 36 is formed at the bottom surface of the self-adhesive layer 100.

The sealing portion 102 is structured from a first sealing film 102A that is at the reflecting plate 60 side and a second sealing film 102B that is at the self-adhesive layer 100 side. Although these first sealing film 102A and second sealing film 102B are differentiated because they are formed separately, there is no particular difference in the materials or the like thereof.

A material having a barrier ability with respect to moisture in the atmosphere is used for the respective sealing films 102A, 102B. An organic film obtained by vapor-phase polymerization such as thermal CVD, plasma CVD or the like is used as the material. A vapor-phase polymer film formed by thermal CVD of polyparaxylene resin, or a plasma polymer film of a plasma polymer film unsaturated hydrocarbon monomer of a fluorine-containing composite unsaturated hydrocarbon monomer, is used as the organic film. Or, a laminated structure of an organic film and an inorganic film can be used. As the material of the inorganic film, a silicon nitride (SiNx) film, a silicon oxide (SiOx) film, a silicon oxynitride (SiOxNy) film, Al₂O₃, and the like are suitable.

The scintillator layer 36 that is enclosed by the sealing portion 102 has a columnar structure. Concretely, the scintillator layer 36 is formed from plural columnar crystals.

Further, the scintillator layer 36 may be formed from a columnar crystal region 36A, that is formed from plural columnar crystals and faces the light detecting substrate 30, and a non-columnar crystal region 36B, that is formed from plural non-columnar crystals and is continuous with the columnar crystal region 36A and faces the reflecting plate 60.

In this columnar crystal region 36A, columnar crystals at which efficient light-emission is obtained exist in the vicinity of the light detecting substrate 30, and light is guided through the columnar crystal interiors, and blurring of the image is suppressed due to light diffusion being suppressed. Moreover, the light that reaches the deep portions as well is reflected at the reflecting plate 60, and therefore, the amount of light that the light detecting substrate 30 receives from the scintillator layer 36 can be increased.

Examples of the material of the scintillator layer 36 that has such a columnar structure are CsI:Tl, CsI:Na (sodium activated cesium iodide), ZnS:Cu, CsBr, and the like.

The reflecting plate 60 is provided, via the first sealing film 102A, at the lower side of the non-columnar crystal region 36B of the scintillator layer 36.

The reflecting plate 60 reflects the light, that has been converted at the scintillator layer 36, toward the light detecting substrate 30 side, and is disposed so as to face the scintillator layer 36 so as to be able to be displaced relatively in an in-plane direction P. Note that, when the vertical direction in FIG. 5 is an out-of-plane direction S, the in-plane direction P is the horizontal direction.

The aforementioned “so as to be able to be displaced relatively” means being able to be displaced without being restrained by one another. In the present first exemplary embodiment, this is realized by the reflecting plate 60 being made to planarly contact the scintillator layer 36 (actually, the first sealing film 102A) in a state of not being joined thereto either physically or chemically.

The reflecting plate 60 has a reflecting plate main body 60A and a slide portion 60B.

The reflecting plate main body 60A is rectangular flat plate shaped, and is preferably formed of a material having high reflectance and excellent dimensional stability, heat-resistance and the like. Metal materials such as aluminum, stainless steel and the like, and the like are examples of the material of the reflecting plate main body 60A, but the reflecting plate main body 60A may be a material other than these.

The slide portion 60B is a place that is formed by subjecting the surface of the reflecting plate main body 60A to a sliding treatment, in order to reduce friction with the contact surface of the first sealing film 102A.

Concretely, the slide portion 60B is structured from a structure formed by polishing the surface of the reflecting plate main body 60A, or a structure formed by coating a coating agent such as a fluorine composite, a silicone composite or the like, or oil or the like on the surface of the reflecting plate main body 60A, or the like.

—Operation—

As described above, in accordance with the structure of the radiation detector 20 relating to the first exemplary embodiment of the present invention, even if the thermal expansion amounts (displacement amounts), in the in-plane direction P, of the light detecting substrate 30 and the reflecting plate 60 differ, the reflecting plate 60 and the scintillator layer 36 are disposed so as to face one another and so as to be able to be displaced relatively in the in-plane direction P, i.e., can be displaced without restraining one another. Therefore, warping of the light detecting substrate 30 due to a difference in the thermal expansion amounts of the scintillator layer 36 and the light detecting substrate 30 can be suppressed.

Further, because the reflecting plate 60 has the slide portion 60B at the surface that contacts the first sealing film 102A, the reflecting plate 60, and the first sealing film 102A and the scintillator layer 36, restraining one another and displacing due to friction can be suppressed.

Moreover, the columnar crystal region 36A faces the light detecting substrate 30. Therefore, the distance between the columnar crystal region 36A, at which there is little scattering of light as compared with the non-columnar crystal region 36B, and the light detecting substrate 30 is close, and the amount of light that the light detecting substrate 30 receives from the scintillator layer 36 can be increased.

Further, the radiation detector 20 has the sealing portion 102 that encloses and seals the entire scintillator layer 36. Therefore, water and the like can be prevented from contacting the scintillator layer 36, which is particularly effective in cases in which the scintillator layer 36 is deliquescent.

Moreover, at the radiographic imaging device 10 relating to the first exemplary embodiment of the present invention, the light detecting substrate 30 that is fixed to the housing 16 is the irradiation surface of the radiation X. Therefore, the radiation X hits the scintillator layer 36 and the reflecting plate 60 in that order from the light detecting substrate 30 that is the irradiation surface of the radiation X.

At this time, within the scintillator layer 36, the radiation X is first irradiated onto the scintillator portion at the light detecting substrate 30 side. Therefore, this scintillator portion at the light detecting substrate 30 side mainly absorbs the radiation X and emits light. Further, when the scintillator portion that mainly absorbs the radiation X and emits light within the scintillator layer is the light detecting substrate 30 side, the distance between that scintillator portion and the light detecting substrate 30 is close, and the amount of light that the light detecting substrate 30 receives from the scintillator layer 36 can be increased.

Moreover, in the first exemplary embodiment, in particular, the scintillator portion that mainly absorbs the radiation X and emits light within the scintillator layer 36 is the columnar crystal region 36A at the light detecting substrate 30 side. Therefore, there is even less light scattering, and the amount of light that is received at the light detecting substrate 30 can be increased further.

### Second Exemplary Embodiment

A radiation detector relating to a second exemplary embodiment of the present invention is described next.

—Structure of Radiation Detector—

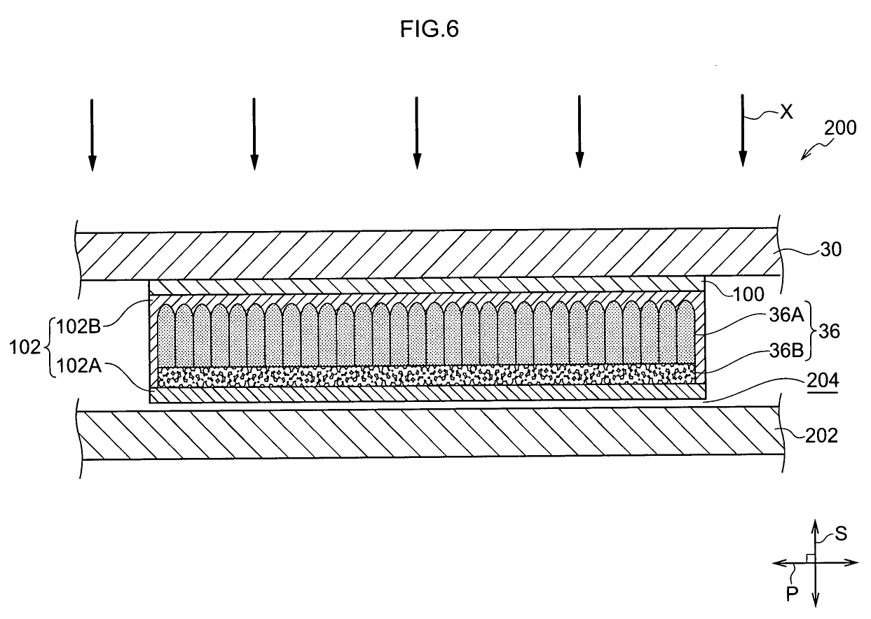

FIG. 6 is a sectional view showing the sectional structure of a radiation detector 200 relating to the second exemplary embodiment of the present invention.

The radiation detector 200 relating to the second exemplary embodiment of the present invention has a reflecting plate 202 that is different from the reflecting plate 60 of the first exemplary embodiment. Note that the other structures are the same as the structures of the radiation detector 20 relating to the first exemplary embodiment.

The reflecting plate 202 of the present second exemplary embodiment is placed on the base 56 (see FIG. 4) so as to face the first sealing film 102A, but does not contact the first sealing film 102A.

Namely, the reflecting plate 202 is supported by the base 56 such that an air layer 204 is formed between the reflecting plate 202 and the first sealing film 102A (the scintillator layer 36).

From the standpoint of increasing the reflectance of the light at the reflecting plate 202, the thickness of the air layer 204 is preferably thin, and is, for example, around several μm.

Concrete examples of the thickness of the air layer 204 are given by using following Table 1.

Table 1 shows the relationship between the thickness of the air layer 204 (the distance between the reflecting plate 202 and the scintillator layer 36) and sensitivity, and the relationship between the thickness of the air layer 204 and MTF (resolution).

TABLE 1

| thickness (μm) | 0 | 5 | 10 | 15 | 20 | 30 | 50 |
|---|---|---|---|---|---|---|---|
| sensitivity | 100 | 110 | 110 | 110 | 110 | 105 | 90 |
| (relative value) | | | | | | | |
| MTF (relative | 100 | 100 | 99 | 97 | 95 | 90 | 75 |
| value) | | | | | | | |

From the concrete examples shown in Table 1, it can be understood that, from the standpoint of increasing the sensitivity (increasing the reflectance of light at the reflecting plate 202), the thickness of the air layer 204 is preferably in a range exceeding 0 μm and less than or equal to 30 μm, and more preferably in a range exceeding 0 μm and less than or equal to 20 μm.

Further, it can be understood that, from the standpoint of improving both sensitivity and the MTF, a range exceeding 0 μm and less than or equal to 10 μm is more preferable.

—Operation—

As described above, in accordance with the radiation detector 200 relating to the second exemplary embodiment of the present invention, the reflectance of light at the reflecting plate 202 can be increased owing to the effects of the refractive index of the air layer 204.

### Third Exemplary Embodiment

A radiation detector relating to a third exemplary embodiment of the present invention is described next.

—Structure of Radiation Detector—

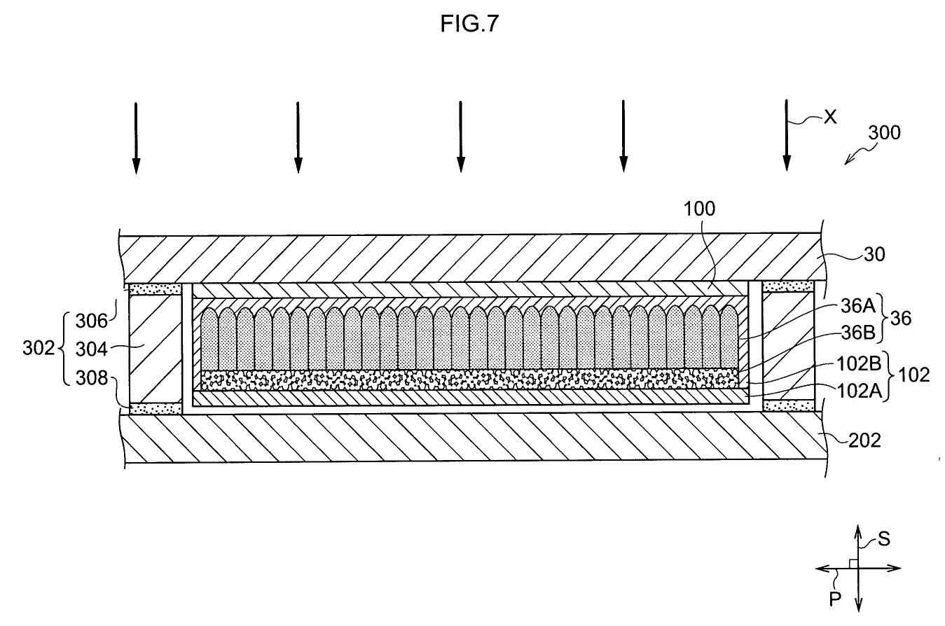

FIG. 7 is a sectional view showing the sectional structure of a radiation detector 300 relating to the third exemplary embodiment of the present invention.

The radiation detector 300 relating to the third exemplary embodiment of the present invention has the same structure as the second exemplary embodiment, and further, a frame portion 302 is added.

The frame portion 302 of the present third exemplary embodiment has a frame member 304 that encloses the outer peripheral portion of the scintillator layer 36 (the sealing portion 102) with a gap therebetween.

The frame member 304 extends toward the out-of-plane direction S of the radiation detector 300, and is fixed to the light detecting substrate 30 by an adhesive 306, and further, is fixed to the reflecting plate 202 by an adhesive 308. Accordingly, the light detecting substrate 30 and the reflecting plate 202 are connected via the frame member 304.

However, even though the light detecting substrate 30 and the reflecting plate 202 are connected in this way, the frame member 304 is made to be flexible, and the light detecting substrate 30 (and the scintillator layer 36) and the reflecting plate 202 can be displaced without being restrained by one another. Accordingly, the frame member 304 is structured by an ultraviolet-curing-type acrylic adhesive, or a silicone or epoxy adhesive, or the like. Note that the frame member 304 may be omitted, and the frame portion 302 can be structured by only the adhesives 306, 308.

—Operation—

As described above, in accordance with the radiation detector 300 relating to the third exemplary embodiment of the present invention, the scintillator layer 36 is enclosed by the frame portion 302 in addition to the sealing portion 102. Therefore, water and the like can be reliably prevented from contacting the scintillator layer 36.

### Fourth Exemplary Embodiment

A radiation detector relating to a fourth exemplary embodiment of the present invention is described next.

—Structure of Radiation Detector—

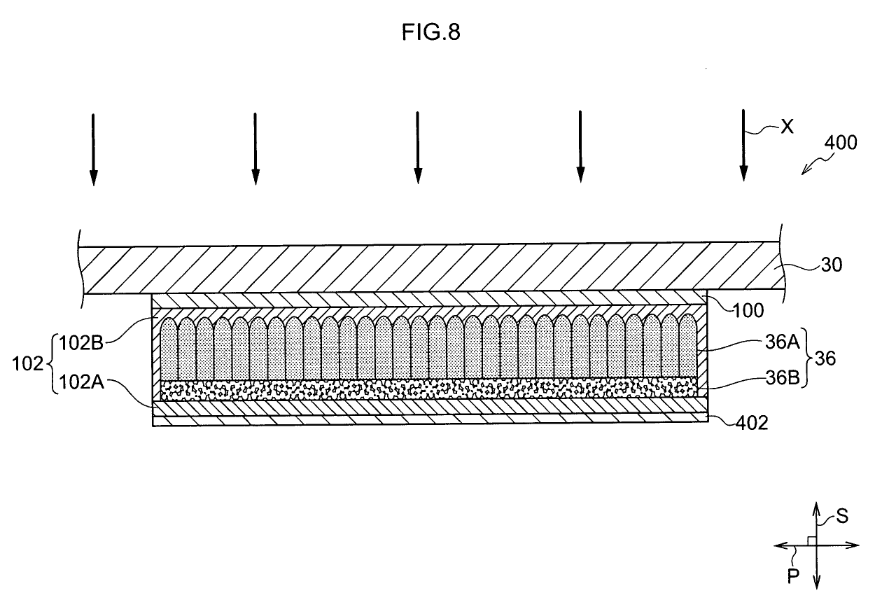

FIG. 8 is a sectional view showing the sectional structure of a radiation detector 400 relating to the fourth exemplary embodiment of the present invention.

The radiation detector 400 relating to the fourth exemplary embodiment of the present invention has a reflecting thin film 402 instead of the reflecting plate 60 of the first exemplary embodiment. Note that the other structures are the same as the structures of the radiation detector 20 relating to the first exemplary embodiment.

Differently than the reflecting plate 60, the reflecting thin film 402 of the present fourth exemplary embodiment contacts the first sealing film 102A in a joined state. The reflecting thin film 402 is formed by CVD, plasma CVD, vacuum deposition, sputtering, or the like, and is made to be a thin film. Therefore, the thickness of the reflecting thin film 402 is thinner than that of the reflecting plate 60.

The thickness of the reflecting thin film 402 is, for example, greater than or equal to 0.1 μm and less than or equal to 100 μm. From the standpoint of suppressing warping due to a difference in thermal expansion between the reflecting thin film 402 and the light detecting substrate 30, the thickness of the reflecting thin film 402 is preferably greater than or equal to 0.1 μm and less than or equal to 10 μm.

—Operation—

In general, the amount of displacement (amount of thermal expansion) of a reflecting portion is proportional to the thickness thereof. In accordance with the radiation detector 400 relating to the fourth exemplary embodiment of the present invention, the reflecting thin film 402 is made to be a thin film, and therefore, the amount of displacement of the reflecting thin film 402 can be reduced, and accordingly, warping of the light detecting substrate 30 can be suppressed.

Further, in accordance with this structure, in the same way as in the first exemplary embodiment, the radiation X hits the scintillator layer 36 and the reflecting thin film 402 in that order from the light detecting substrate 30.

At this time, the radiation X is first irradiated onto the scintillator portion at the light detecting substrate 30 side within the scintillator layer 36. Therefore, this scintillator portion at the light detecting substrate 30 side mainly absorbs the radiation X and emits light. Further, when the scintillator portion that mainly absorbs the radiation X and emits light within the scintillator layer is the light detecting substrate 30 side, the distance between that scintillator portion and the light detecting substrate 30 is close, and the amount of light that is received at the light detecting substrate 30 can be increased.

### Fifth Exemplary Embodiment

A method of fabricating a radiation detector relating to a fifth exemplary embodiment of the present invention is described next.

—Structure of Radiation Detector—

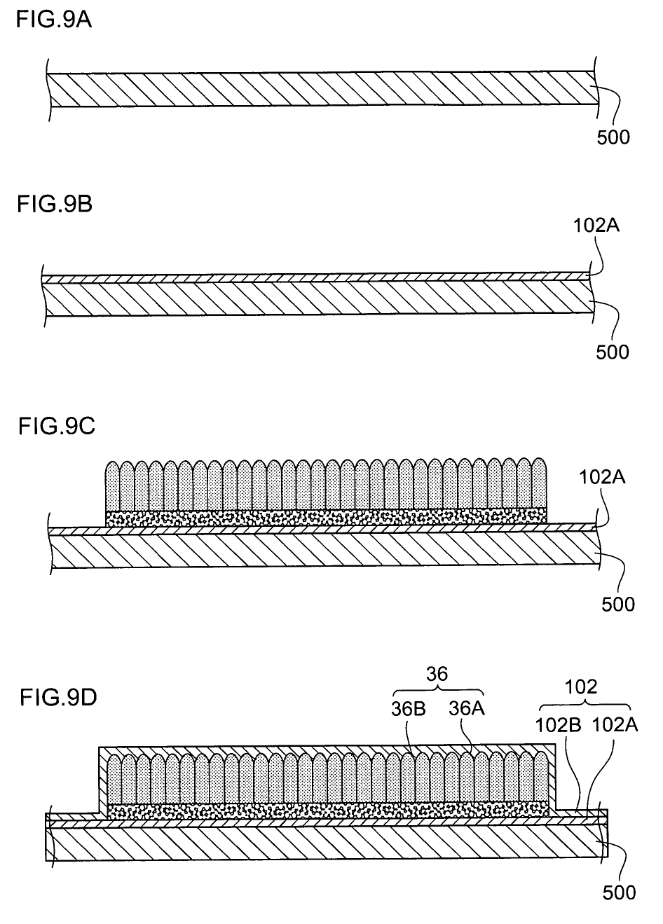

FIG. 9A through FIG. 9D are process diagrams of the method of fabricating a radiation detector relating to the fifth exemplary embodiment of the present invention. Although the method of fabricating a radiation detector relating to the fifth exemplary embodiment of the present invention is described with the radiation detector having the same structure as the structure of the radiation detector 20 of the first exemplary embodiment for example, the radiation detectors of the second exemplary embodiment through the fourth exemplary embodiment also can be fabricated by this fabrication method.

1. Substrate Readying Process

First, as shown in FIG. 9A, a substrate readying process in which a supporting substrate 500 is readied is carried out.

For example, aluminum or carbon can be used as the material of the supporting substrate 500.

2. Releasing Processing Process

Next, a releasing processing process is carried out in which a releasing agent is coated on the surface of the supporting substrate 500, in order for the adhesive strength between the supporting substrate 500 and the first sealing film 102A, that is to be formed after, to be lower than the adhesive strength between the first sealing film 102A and the scintillator layer 36.

However, the amount of the releasing agent must be made to be small, or the releasing agent must be coated on only a portion of the surface of the supporting substrate 500, or the like appropriately, in order for the supporting substrate 500 to not be peeled off at the time of formation of the scintillator layer 36 that is described hereafter.

3. First Sealing Film Forming Process

Next, as shown in FIG. 9B, a first sealing film forming process is carried out in which the first sealing film 102A, that structures the sealing portion 102, is formed on the supporting substrate 500.

Examples of the method of forming the first sealing film 102A are chemical type printing methods such as CVD, plasma CVD and the like, and physical methods such as vapor deposition, sputtering, ion plating and the like, and wet methods such as coating and the like.

The method of forming the first sealing film 102A may be selected appropriately in accordance with the material that is used.

4. Scintillator Layer Forming Process

Next, as shown in FIG. 9C, a scintillator layer forming process is carried out that forms the scintillator layer 36 on the first sealing film 102A by a vapor depositing method. Concretely, a mode using CsI:Tl is described as an example.

The vapor depositing method can be carried out in accordance with a usual method. Namely, in an atmosphere of a degree of vacuum of 0.01 to 10 Pa, it suffices to heat and vaporize the CsI:Tl by a means such as supplying electricity to a resistance-heating-type pot, and to deposit the CsI:Tl on the supporting substrate 500 (the first sealing film 102A) with the temperature (deposition temperature) of the supporting substrate 500 being room temperature (20° C.) to 300° C.

When the crystal phase of the CsI:Tl is formed on the first sealing film 102A by a vapor depositing method, initially, an aggregation of crystals that are irregularly-shaped or are substantially spherical crystals and whose diameter is relatively small is formed. At the time of implementing the vapor depositing method, by changing at least one condition among the degree of vacuum and the temperature of the supporting substrate 500, columnar crystals can be grown by the vapor depositing method continuously after the formation of the non-columnar crystal region 36B.

Namely, after the non-columnar crystal region 36B is formed, by carrying out at least one of means such as raising the degree of vacuum or increasing the temperature of the supporting substrate 500 or the like, uniform columnar crystals are grown efficiently, and the columnar crystal region 36A can be formed.

5. Second Sealing Film Forming Process

Next, as shown in FIG. 9D, a second sealing film forming processing is carried out in which the second sealing film 102B that structures the sealing portion 102 is formed so as to cover the scintillator layer 36 and the first sealing film 102A. The method of forming the second sealing film 102B is similar to the method of forming the first sealing film 102A.

6. Affixing Process

Next, although not illustrated, an affixing process is carried out in which the light detecting substrate 30 is affixed on the second sealing film 102B via the self-adhesive layer 100.

7. Removal Process

Next, although not illustrated, a removal process is carried out in which the supporting substrate 500 is removed from the first sealing film 102A.

8. Reflecting Substrate Placement Process

Next, although not illustrated, the reflecting plate 60 is disposed so as to planarly-contact the first sealing film 102A in a state of not being joined thereto.

9. Acquisition of Radiation Detector 20

The radiation detector 20 shown in FIG. 5 can be acquired through the above-described processes.

—Operation—

As described above, in accordance with the method of fabricating a radiation detector relating to the fifth exemplary embodiment of the present invention, due to the releasing processing process, the adhesive strength between the supporting substrate 500 and the first sealing film 102A is made to be lower than the adhesive strength between the first sealing film 102A and the scintillator layer 36. Therefore, in the removal step of removing the supporting substrate 500 from the first sealing film 102A, the supporting substrate 500 can be easily removed without peeling the first sealing film 102A off from the scintillator layer 36.

### Sixth Exemplary Embodiment

A method of fabricating a radiation detector relating to a sixth exemplary embodiment of the present invention is described next.

—Structure of Radiation Detector—

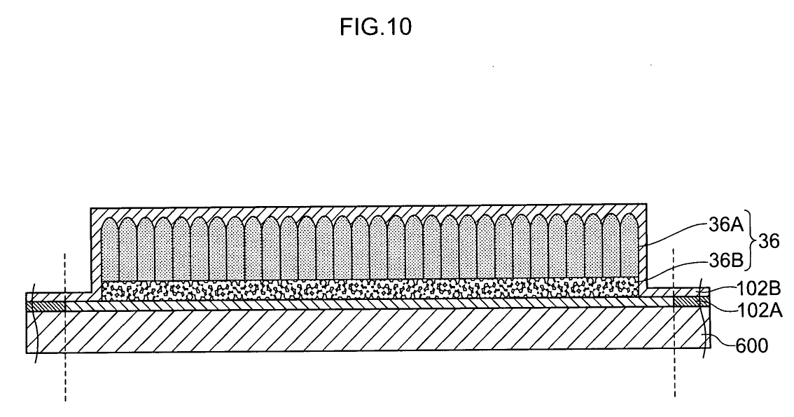

FIG. 10 is an explanatory drawing of the method of fabricating a radiation detector relating to the sixth exemplary embodiment of the present invention. Although the method of fabricating a radiation detector relating to the sixth exemplary embodiment of the present invention is described with the radiation detector having the same structure as the structure of the radiation detector 20 of the first exemplary embodiment for example, the radiation detectors of the second exemplary embodiment through the fourth exemplary embodiment also can be fabricated by this fabrication method. Note that portions of the method and the like that are not described hereinafter are similar to the method of fabricating a radiation detector relating to the fifth exemplary embodiment.

1. Substrate Readying Process

First, a substrate readying process in which a supporting substrate 600 is readied is carried out.

2. Surface Treatment Process

Next, a surface treatment process is carried out in which a surface treatment is carried out on the supporting substrate 600 at the outer peripheral side, so that the adhesive strength between the first sealing film 102A, that is at the outer peripheral side of the formation region of the scintillator layer 36 that is described later, and the supporting substrate 600 becomes higher than the adhesive strength between the first sealing film 102A, that is beneath the formation region of the scintillator layer 36, and the supporting substrate 600.

Examples of this surface treatment are cleaning the surface of the supporting substrate 600 with an organic solvent or an alkali cleaning liquid or the like, a method of providing minute indentations and projections at the surface by a sandblasting treatment, a method of improving the adhesion of the surface by a primer treatment, and the like.

3. First Sealing Film Forming Process

Next, a first sealing film forming process is carried out in which the first sealing film 102A, that structures the sealing portion 102, is formed on the supporting substrate 500. Note that, in FIG. 10, the first sealing film 102A is sectioned into two portions. However, only the adhesive strengths of these portions with the supporting substrate 600 differ, and the structural materials and methods of fabrication thereof are the same.

4. Scintillator Layer Forming Process

Next, a scintillator layer forming process is carried out that forms the scintillator layer 36 on the first sealing film 102A by a vapor depositing method.

5. Second Sealing Film Forming Process

Next, a second sealing film forming process is carried out in which the second sealing film 102B that structures the sealing portion 102 is formed so as to cover the scintillator layer 36 and the first sealing film 102A.

6. Cutting Process

Next, a cutting process is carried out in which the first sealing film 102A and the second sealing film 102B, that are at the outer peripheral side of the scintillator layer 36, are cut in the out-of-plane direction (at the places shown by the dashed lines in the drawing) of the supporting substrate 600.

7. Affixing Process

Next, although not illustrated, an affixing process is carried out in which the light detecting substrate 30 is affixed on the second sealing film 102B via the self-adhesive layer 100.

8. Removal Process

Next, although not illustrated, a removal process is carried out in which the supporting substrate 600 is removed from the first sealing film 102A.

9. Reflecting Substrate Placement Process

Next, although not illustrated, the reflecting plate 60 is disposed so as to planarly-contact the first sealing film 102A in a state of not being joined thereto.

10. Acquisition of Radiation Detector 20

The radiation detector 20 shown in FIG. 5 can be acquired through the above-described processes.

—Operation—

As described above, in accordance with the method of fabricating a radiation detector relating to the sixth exemplary embodiment of the present invention, at the time of the scintillator layer forming process, the adhesive strength between the first sealing film 102A, that is at the outer peripheral side of the formation region of the scintillator layer 36, and the supporting substrate 600 is higher than the adhesive strength between the first sealing film 102A, that is beneath the formation region of the scintillator layer 36, and the supporting substrate 600. Therefore, for example, the first sealing film 102A and the scintillator layer 36 can be prevented from being peeled-off from the supporting substrate 600.

Further, at the time of the removal process that removes the supporting substrate 600 from the first sealing film 102A, the first sealing film 102A, whose adhesive strength at the outer peripheral side of the scintillator layer 36 is high, and the second sealing film 102B are cut in the out-of-plane direction of the supporting substrate 600. Therefore, it suffices to remove the supporting substrate 600 only from the first sealing film 102A that is beneath the formation region of the scintillator layer 36. Here, the adhesive strength between the first sealing film 102A, that is beneath the formation region of the scintillator layer 36, and the supporting substrate 600 is lower than the adhesive strength between the first sealing film 102A, that is at the outer peripheral side of the formation region of the scintillator layer 36, and the supporting substrate 600. Therefore, the supporting substrate 600 can be removed easily.

### MODIFIED EXAMPLES

Although the present invention has been described in detail with reference to specific exemplary embodiments, the present invention is not limited to these exemplary embodiments, and it will be clear to those skilled in the art that other various embodiments are possible within the scope of the present invention. For example, the above-described plural exemplary embodiments can be implemented by being combined appropriately. Further, the following modified examples may be combined appropriately.

For example, instead of the reflecting plate 60 of the first exemplary embodiment, a structure whose cross-section is another shape such as semicircular, oval, triangular or the like, or a reflecting portion such as a reflecting thin film or the like can be provided. Further, the slide member 60B may be provided at the surface of the first sealing film 102A, and not the surface of the reflecting plate main body 60A. Or, the slide member 60B may be provided at both the surface of the reflecting plate main body 60A and the surface of the first sealing film 102A.

Further, the slide member 60B and the sealing portion 102 can be omitted.

Although a case is described in which the scintillator layer 36 has a columnar structure, there may be a case in which the scintillator layer 36 does not have a columnar structure such as, for example, a case in which the scintillator layer 36 is formed by coating a scintillator formed from GOS (Gd₂O₂S:Tb) or the like on the light detecting substrate 30, or the like.

Further, description is given of a case in which the columnar crystal region 36A faces the light detecting substrate 30, and the non-columnar crystal region 36B faces the reflecting plate 60, but a structure that is opposite may be employed.

Moreover, the scintillator layer 36 that is structured only by the columnar crystal region 36A and not the non-columnar crystal region 36B may be used.

The first through fourth exemplary embodiments describe the so-called reverse surface irradiation type radiographic imaging device 10 in which the light detecting substrate 30 is the irradiation surface of the radiation X. However, a so-called obverse surface irradiation type radiographic imaging device, in which the scintillator layer 36 side is the irradiation surface of the radiation X, may be used except in the case of the fourth exemplary embodiment.

Further, in FIG. 6 that is described in the second exemplary embodiment, a spacer that makes the distance between the reflecting plate 202 and the scintillator layer 36 constant may be provided between the reflecting plate 202 and the scintillator layer 36 (the first sealing film 102A). The spacer may be structured by plural fine particles, or may be formed in the form of lines, a mesh or spots that are formed by a resist or the like, or the like. By doing so, the scintillator layer 36 can be supported by the spacer.

The second exemplary embodiment describes a case in which the reflecting plate 202 is placed on the base 56, but the reflecting plate 202 may be fixed to the housing 16.

Further, the fifth exemplary embodiment describes a case in which the releasing processing process is carried out before the first sealing film forming process. However, a surface treatment, that increases the adhesive strength between the first sealing film 102A and the scintillator layer 36 in order for the adhesive strength between the supporting substrate 500 and the first sealing film 102A to be lower than the adhesive strength between the first sealing film 102A and the scintillator layer 36, may be carried out after the first sealing film forming process and before the scintillator layer forming process.

In the sixth exemplary embodiment, the cutting process is carried out after the second sealing film forming process and before the affixing process, but the cutting process may be carried out after the affixing process and before the removing process. Further, it is described that, in the cutting process, the supporting substrate 600, the first sealing film 102A and the second sealing film 102B are all cut. However, it is possible to cut only the first sealing film 102A and the second sealing film 102B, or cutting to halfway through the supporting substrate 600 is possible.

Moreover, the first exemplary embodiment describes a case in which the radiation detector 20, that detects the radiation X that has passed through the patient 14, and the control substrate 22 are provided within the housing 16 in that order from the irradiation surface 18 side of the housing 16 onto which the radiation X is irradiated. However, a grid that removes scattered radiation of the radiation X that arises accompanying the passing through the patient 14, and the radiation detector 20, and a lead plate that absorbs the back-scattered radiation of the radiation X, may be accommodated in that order from the irradiation surface 18 side onto which the radiation X is irradiated.

Although the first exemplary embodiment describes a case in which the shape of the housing 16 is rectangular plate shaped, the shape of the housing 16 is not particularly limited, and may be, for example, square or circular in front view.

Further, although the first exemplary embodiment describes a case in which the one control substrate 22 is formed, the present invention is not limited to this exemplary embodiment, and the control substrate 22 may be divided into plural control substrates per function. Moreover, although a case is described in which the control substrate 22 is disposed so as to be lined-up next to the radiation detector 20 in the vertical direction (the thickness direction of the housing 16), the control substrate 22 may be disposed so as to be lined-up next to the radiation detector 20 in the horizontal direction.

The radiation X is not limited to X-rays, and may be α rays, β rays, γ rays, an electron beam, ultraviolet rays, or the like.

Further, although a case is described in which the radiographic imaging device 10 is an electronic cassette that is portable, the radiographic imaging device may be a large radiographic imaging device that is not portable.

What is claimed is:

1. A radiation detector comprising:
a light detecting substrate that converts light into charges;
a scintillator layer that faces the light detecting substrate and converts irradiated radiation into light; and
a reflecting portion that reflects light, converted at the scintillator layer, toward the light detecting substrate, and is disposed so as to face the scintillator layer and so as to be able to be displaced relative to the scintillator layer in an in-plane direction.

2. The radiation detector of claim 1, wherein the reflecting portion planarly contacts the scintillator layer.

3. The radiation detector of claim 2, wherein a contact surface of the reflecting portion or the scintillator layer is subjected to a sliding treatment.

4. The radiation detector of claim 1, wherein the reflecting portion is supported such that an air layer is formed between the reflecting portion and the scintillator layer.

5. The radiation detector of claim 4, wherein a spacer, that makes a distance between the reflecting portion and the scintillator layer constant, is provided between the reflecting portion and the scintillator layer.

6. The radiation detector of claim 1, wherein the scintillator layer is structured so as to include a plurality of columnar crystals.

7. The radiation detector of claim 6, wherein distal ends of the columnar crystals face the light detecting substrate.

8. The radiation detector of claim 1, further comprising a sealing portion that encloses and seals the entire scintillator layer.

9. The radiation detector of claim 1, further comprising a frame portion that connects the light detecting substrate and the reflecting portion.

10. A radiographic imaging device comprising:
a housing; and
the radiation detector of claim 1, incorporated within the housing,
wherein the light detecting substrate of the radiation detector is an irradiation surface of the radiation.

11. A radiographic imaging device comprising:
a housing; and
the radiation detector of claim 1, incorporated within the housing,
wherein the reflecting portion of the radiation detector is supported at the housing.

12. A radiographic imaging device comprising a housing and a radiation detector incorporated within the housing, wherein the radiation detector comprises, in order from an irradiating direction of radiation:
a light detecting substrate that converts light into charges;
a scintillator layer that is disposed such that the light detecting substrate and distal ends of columnar crystals face one another, and that converts the irradiated radiation into light; and
a reflecting portion that is layered as a thin film on surfaces of ends, opposite the distal ends, of the columnar crystals, and that reflects, toward the light detecting substrate, light converted at the scintillator layer.

13. A method of fabricating the radiation detector of claim 8, comprising:
forming, on a supporting substrate, a first sealing film that structures the sealing portion;
forming the scintillator layer on the first sealing film;
forming a second sealing film, that structures the sealing portion, so as to cover the scintillator layer and the first sealing film;
affixing the light detecting substrate on the second sealing film; and
removing the supporting substrate from the first sealing film,
wherein, before forming the first sealing film, or after forming the first sealing film and before forming the scintillator layer, a surface treatment is carried out on the supporting substrate or the first sealing film such that an adhesive strength between the supporting substrate and the first sealing film is lower than an adhesive strength between the first sealing film and the scintillator layer.

14. A method of fabricating the radiation detector of claim 8, comprising:
forming, on a supporting substrate, a first sealing film that structures the sealing portion;
forming the scintillator layer on the first sealing film;
forming a second sealing film, that structures the sealing portion, so as to cover the scintillator layer and the first sealing film;
affixing the light detecting substrate on the second sealing film;
cutting, after forming the second sealing film and before affixing the light detecting substrate, or after affixing the light detecting substrate, in an out-of-plane direction of the supporting substrate, the first sealing film and the second sealing film, which are at an outer peripheral side of the scintillator layer; and
removing the supporting substrate from the first sealing film,
wherein, before forming the first sealing film, a surface treatment is carried out on the supporting substrate such that an adhesive strength between the supporting substrate and a portion of the first sealing film, that is at an outer peripheral side of a formation region of the scintillator layer, is higher than an adhesive strength between the supporting substrate and a portion of the first sealing film that is beneath the formation region of the scintillator layer.
